(19) United States
(12) Patent Application Publication
(10) Pub. No.: US 2025/0246432 A1
(43) Pub. Date: Jul. 31, 2025

(54) INTEGRATED CIRCUIT WITH CORRUGATED CHANNEL STRUCTURES HAVING CONTROLLED DOPING PROFILE OVER CHANNEL TOPOGRAPHY

(71) Applicant: TEXAS INSTRUMENTS INCORPORATED, Dallas, TX (US)

(72) Inventors: Christopher Thompson, Salt Lake City, UT (US); Brian Ellingwood, Millcreek, UT (US); Robert Cassel, Lehi, UT (US); Jackson Bauer, Rowlett, TX (US); Sheldon Douglas Haynie, Dallas, TX (US)

(21) Appl. No.: 18/428,095

(22) Filed: Jan. 31, 2024

(51) Int. Cl. H01L 21/266; H01L 21/265; H01L 21/311; H01L 29/78

(52) U.S. Cl. CPC H01L 21/266; H01L 21/26586; H01L 21/31111; H10D 30/6211; H10D 30/65

(57) ABSTRACT

An integrated circuit (IC) device including one or more corrugated channel structures formed in or over a semiconductor substrate, where a corrugated channel structure includes a first sidewall, a second sidewall and a top surface. In an example, the corrugated channel structure is provided with a substantially uniform distribution profile of a dopant across a horizontal plane from the first sidewall to the second sidewall.

### FIELD OF THE DISCLOSURE

Disclosed implementations relate generally to the field of integrated circuits (ICs) and IC fabrication. More particularly, but not exclusively, the disclosed implementations relate to an IC device including one or more corrugated channel structures.

### BACKGROUND

FinFETs are a type of three-dimensional (3D) MOSFET transistor where the channel includes a non-planar structure resembling a “fin” and comprises semiconductor material protruding from a semiconductor substrate. FinFETs are regarded as candidates for use in future advanced CMOS technology nodes due to the FinFET's superior gate control over the channel, resulting in faster switching times, improved short-channel effect immunity, higher current densities, and improved Iₒₙ/I_{off} ratios. As the integration of FinFET technologies continues to become more prevalent, demands for improvements in various aspects of the FinFET design are increasing.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to an IC device and its fabrication, where the IC device may include one or more corrugated channel structures formed in or over a semiconductor substrate. Each corrugated channel structure may include a first sidewall, a second sidewall and a top surface. In an example, the corrugated channel structure is provided with a substantially uniform distribution profile of a dopant over the channel topography based on a selective implant blocking scheme.

In one example, a method of fabricating an IC device is disclosed. The method may comprise, among others, forming a corrugated channel structure over a semiconductor substrate, the corrugated channel structure including a sidewall and a top surface; forming a top oxide cap over the top surface; implanting a first dopant in the sidewall in a first implant; removing the top oxide cap; and implanting a second dopant in the top surface. In some arrangements, the top oxide cap may be formed by atomic layer deposition (ALD) or physical vapor deposition (PVD) of the top surface.

In one example, a method of fabricating an IC device is disclosed. The method may comprise, among others, forming a plurality of corrugated channel structures over a semiconductor substrate, the plurality of corrugated channel structures separated by respective trenches formed between adjacent corrugated channel structures, each trench including a bottom surface and each corrugated channel structure including a first sidewall, a second sidewall and a top surface; forming a conformal oxide layer (e.g., using ALD) over the corrugated channel structures; selectively removing the conformal oxide layer from the first and second sidewalls of respective corrugated channel structures, where a remaining portion of the conformal oxide layer forms a top oxide cap over the top surface of each respective corrugated channel structure and a bottom oxide cap over the bottom surface of each respective trench; implanting a first dopant in the first and second sidewalls of the respective corrugated channel structures using a nonzero beamline tilt angle with respect to a surface normal of the semiconductor substrate; removing the top and bottom oxide caps; and implanting a second dopant in the top surfaces of the respective corrugated channel structures and in the bottom surfaces of the respective trenches using a beamline tilt angle about parallel to the surface normal of the semiconductor substrate.

In one example, a method of fabricating an IC device is disclosed. The method may comprise, among others, forming a plurality of corrugated channel structures over a semiconductor substrate, the plurality of corrugated channel structures separated by respective trenches formed between adjacent corrugated channel structures, each trench including a bottom and each corrugated channel structure including a first sidewall, a second sidewall and a top surface; selectively forming (e.g., using PVD) a top oxide cap over the top surface of each respective corrugated channel structure and a bottom oxide cap over the bottom of each respective trench; implanting one or more dopants in the first and second sidewalls of the respective corrugated channel structures using one or more beamline tilt angles with respect to a surface normal of the semiconductor substrate; removing the top and bottom oxide caps; and implanting, in a vertical implant, one or more dopants in the top surfaces of the respective corrugated channel structures and in the bottoms of the respective trenches.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described. Shapes depicted in the drawings attached are simplified for ease of drafting and/or presentation and support of concepts. They do not limit the scope of examples of the present disclosure with respect to size, count, aspect ratio, contour or specific angles and radii of transitions and/or other related features that may be present in an example implementation.

Terms describing a method of construction such as an “implant” and its derivatives are examples and do not reflect all methods of doping the semiconductor material in an example implementation, which could include vapor or gas phase, solid source, liquid source as well as plasma and beamline implant, depending on implementation. Alternative methods are likely and may be used as appropriate in additional and/or alternative arrangements depending on performance, costs and availability, and the like.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A-1C depict aspects and features of an IC device including one or more corrugated channel structures where dopants may be introduced according to some examples of the present disclosure;

FIGS. 2A-2C depict additional aspects and features of an IC device including one or more corrugated channel structures where dopants may be introduced according to some examples of the present disclosure;

FIGS. 3A-3C are flowcharts of IC fabrication methods for conformally doping the corrugated channel structures of an IC device according to some examples of the present disclosure;

FIGS. 4A-4D depict cross-sectional views of an IC device at various stages of formation for fabricating conformally doped corrugated channel structures according to an example of the present disclosure;

FIGS. 5A-5C depict cross-sectional views of an IC device at various stages of formation for fabricating conformally doped corrugated channel structures according to another example of the present disclosure; and

FIG. 6 depicts a simulated dopant profile across a corrugated channel structure according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of IC devices comprising one or more corrugated channel structures and the fabrication thereof will be set forth below in the context of a process flow that includes line-of-sight implantation techniques, e.g., using beamline ion implant systems.

It is desirable that dopant levels across the channel structures having a vertical topography, also referred to herein as corrugated channel structures or fins, have uniform distributions so that the electrical and other performance characteristics of an IC device including the channel structures are better controlled. By way of example, fin-based devices having source/drain extensions such as drain extended metal oxide semiconductor (DEMOS) field effect transistor (FET) devices, laterally diffused MOS (LDMOS) devices, etc., generally require relatively uniform doping levels across various portions of the fin (e.g., across a top portion, a bottom portion and between the two sidewalls forming lateral portions of the fin) for acceptable threshold voltage control and to prevent impact ionization in more heavily doped regions that can be caused by hot carrier phenomena.

FinFETs may also exhibit susceptibility to performance trade-offs such as on-resistance (Rsp) vs. safe operating area (SOA), where SOA may be defined as the voltage and current conditions over which the device can be expected to operate without damage, which in turn may be related to the breakdown voltage of the device, BVDSS. Further, FinFETs are also afflicted with parasitic bipolar effects that may impact the device operation. In both these conditions, it is expected that potential adverse effects may be mitigated by providing more uniform dopant distribution profiles across the topography of the corrugated channel structures.

Beamline ion implant systems based on line-of-sight (LOS) implantation techniques are often used in introducing dopants into various portions of an IC device. A beamline implant in a fin device typically results in higher doping levels at the top of the fin relative to the bottom and sidewalls due to shadowing of the fin bottom and sidewalls by an adjacent fin. The higher doping at the top of the fin occurs because in implanting each side of the fin, the top surface is implanted twice, thereby causing double dosing, which can hinder obtaining uniform levels of dopant distribution in the fins. Moreover, the bottom surfaces of the trenches between the adjacent fins may also be implanted twice depending on the form factors of the fins, sizing/spacing of the trenches, incident angles of the implant, etc., thereby further exacerbating the dopant distribution profiles in the fins and surrounding regions in the device.

Some implant techniques that do not involve line-of-sight implanting, such as plasma-assisted doping (PLAD) or atomic layer deposition (ALD) doping, may be employed in a fabrication flow in an attempt to achieve more uniform dopant distributions in the fin-based devices. Additional methods to obtain uniform dopant profiles may include forming epitaxial silicon with in-situ doping. However, such techniques are generally more expensive, thus adding to manufacturing costs.

Examples of the present disclosure recognize these and other related deficiencies and provide a fabrication flow including an implant blocking scheme for facilitating more uniform dopant distributions by way of conformal doping where the various portions of the fins may be sequentially implanted in a segregated manner. In an example implementation, the fin sidewalls may be first implanted by an angled beamline implant process while protecting the fin top surfaces and trench bottoms between the fins by suitable oxide capping structures. Subsequently, a vertical implant process may be implemented for implanting the top surfaces of the fins and the bottom surfaces of the trenches between the adjacent fins after removing the protective oxide capping. Because of the protection afforded by the oxide capping structures during sidewall implantation, the detrimental effects of double dosing of the fin structures may be avoided or reduced even in high aspect ratio vertical topographies. While such examples provide materials and processes that advantageously allow cost-effective integration of beamline implanting techniques in a FinFET fabrication flow, no particular result is a requirement unless explicitly recited in a particular claim.

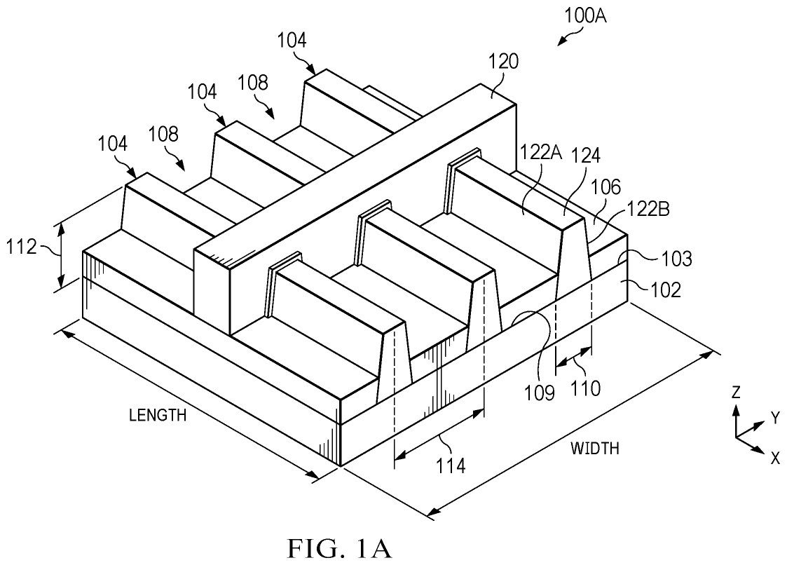

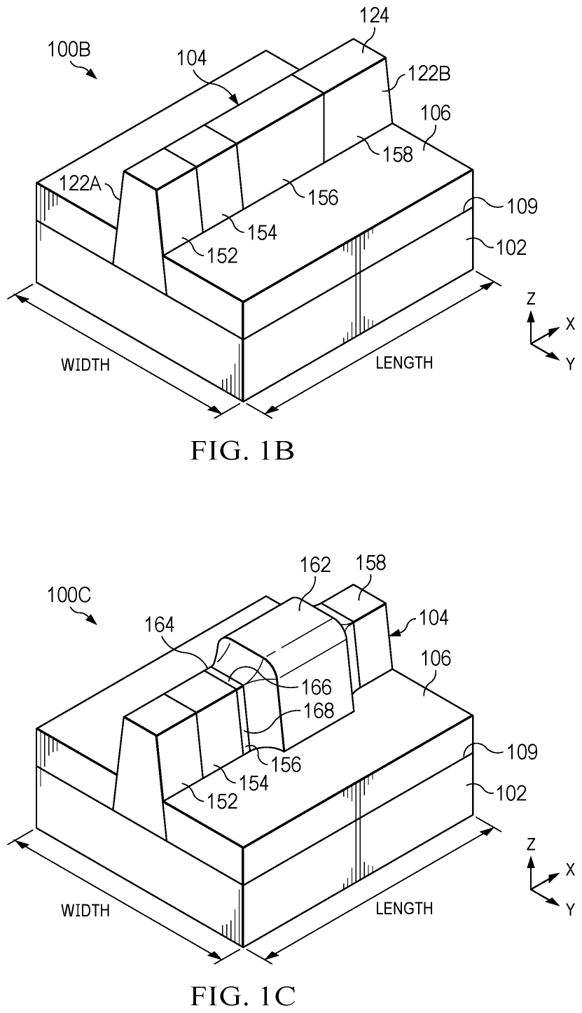

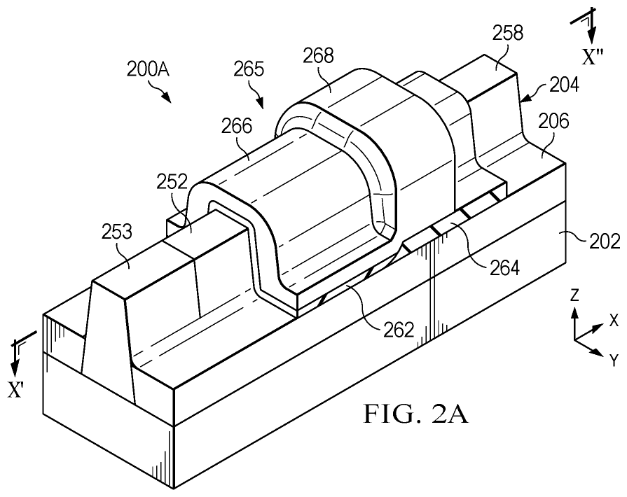

Referring now to the drawing Figures, FIGS. 1A-1C depict various aspects and features of an IC device including one or more corrugated channel structures where dopants may be introduced according to some examples of the present disclosure. In particular, FIG. 1A depicts a 3-dimensional perspective view of an IC device 100A including a plurality of corrugated channel structures 104, or “fins”, separated by trenches 108 formed between the adjacent corrugated channel structures 104, where different portions or regions of the corrugated channel structures 104 and the trenches 108 may be implanted with one or more dopants using beamline implant techniques. Depending on implementation and application, the example IC device 100A may be representative of any type of standalone FinFET device or a portion of an integrated microelectronic device including one or more FinFETs integrated with various other types of circuitry. In some arrangements, the IC device 100A or at least a portion thereof may be illustrative of devices such as, including but not limited to folded DEMOS devices, LDMOS FinFET devices, and FinFETs configured for high voltage power applications (e.g., having appropriate breakdown voltage (Vbd) and specific on-resistance (Rsp) characteristics suitable for operating voltage ranges of 5V to 50V or more), low voltage logic applications, high voltage radio frequency (RF) applications, etc. Further, the IC device 100A may be fabricated in a silicon or other semiconductor material as noted below, e.g., as a bulk FinFET, epitaxial FinFET, silicon-on-insulator (SOI) FinFET, etc., depending on implementation and/or application.

As illustrated, the corrugated channel structures 104 may be formed in a semiconductor substrate 102 or a region of the substrate 102 of the IC device 100A, which may comprise any suitable semiconductor material having appropriate conductivity type (e.g., in a bulk material or in a well region, etc.). In disclosed examples, the semiconductor substrate material may have a first conductivity type, e.g., p-type. Each corrugated channel structure 104 includes a top surface 124, a first sidewall 122A and a second sidewall 122B, and may be separated from adjacent corrugated channel structures 104 by trenches 108 having a bottom surface 109. In some examples, the trenches 108 may be formed by a suitable anisotropic etch, e.g., reactive ion etch (RIE) process using fluorine radicals, in association with appropriately patterned masking. By way of example, the trenches 108 may have an average depth of 300 nanometers (nm) to 1200 nm or more, which corresponds to an average vertical height 112 of the corrugated channel structures 104 in a Z-direction along a surface normal relative to a top major surface, e.g., surface 103, of the semiconductor substrate 102 after the formation of the corrugated channel structures 104. Depending on design rules, the corrugated channel structures 104 may repeat along the Y-direction with a pitch distance 114. In some arrangements, the sidewalls 122A, 122B of the corrugated channel structures 104 may be slanted or angled such that the respective corrugated channel structure 104 may be formed as a tapered structure where an upper portion including the top surface 124 may have a width that is about 40% to 50% of the height 112 of the corrugated channel structure 104. In some arrangements, a lower portion of the corrugated channel structure 104 may have a width 110 that is about 50% to 60% of the height 112 of the corrugated channel structure 104. Accordingly, the sidewalls 122A, 122B may comprise slanted surfaces having angles of around 80° to 89° with respect to a horizontal surface, e.g., the bottom surface 109 of the trenches 108 and/or the top major surface 103, in some examples. Further, representative heights 112, widths 110 and pitches 114 associated with the plurality of corrugated channel structures 104 may be varied generally or individually. Whereas the depth of the trenches 108 is usually consistent, it may vary with trench width in some examples. Sidewall angles and shapes may vary from the examples shown in the drawing Figures and may be optimized for different process/device attributes.

In some arrangements, the IC device 100A may include an isolation structure 106 that may be formed over the substrate 102 for providing dielectric isolation with respect to an electrode structure 120 formed over the corrugated channel structures 104. In some arrangements, the isolation structure 106 may be formed in a shallow trench isolation (STI) process, which may include depositing a dielectric material, such as silicon dioxide, on the substrate 102 to fill a trench space about the corrugated channel structures 104 and etching the dielectric material to a desired thickness, thereby exposing a desired vertical topography of the corrugated channel structures 104. In some arrangements, the electrode structure 120 may comprise a polysilicon gate isolated from the corrugated channel structures 104 by a suitable gate oxide. Depending on operating voltage requirements, e.g., in high voltage applications involving voltages >5V, an optional thick oxide layer may be provided, which may be operable as a field plate oxide (not shown in this Figure) formed over the corrugated channel structures 104.

FIGS. 1B and 1C depict portions 100B and 100C, respectively, of the IC device 100A, where an example corrugated channel structure 104 is shown with additional details or features according to some examples. As illustrated in FIG. 1B, the corrugated channel structure 104 may comprise multiple regions or portions, e.g., a source region 152, a body region 154, a drift region 156 and a drain region 158, which may be formed by introducing suitable dopant species into selected regions of the corrugated channel structures 104 using one or more implant steps in conjunction with appropriate masking and photolithography processes before STI and gate formation. As will be set forth further below, a back gate (BG) region as well as double-diffused well (DWELL) regions (not shown in this Figure) may also be formed proximate to the source region 152 in some example corrugated channel structures based on additional and/or optional doping steps in some arrangements. In accordance with the teachings of the present disclosure, various dopant species may be introduced into different regions of the corrugated channel structures 104 in a segregated manner where the different components of the corrugated channel structures 104, e.g., respective top surfaces 124 and sidewall surfaces 120A, 120B, as well as adjacent trench bottom surfaces 109 may be selectively blocked and unblocked for achieving conformal doping across the vertical topographies of the different regions.

FIG. 1C illustrates an IC device portion 100C including a field plate (FP) dielectric layer 162 formed around a portion of the drift region 156 of the corrugated channel structure 104 in an example. As depicted, the FP dielectric layer 162 may be formed on three sides, e.g., side 164, side 166, and side 168, of the drift region 156. Although not shown in this Figure, a gate oxide formed over the body region 154 extends from the FP dielectric layer 162. As noted previously, the formation of FP dielectric layer 162 is optional, depending on the voltage application in which the IC device 100A is intended to be deployed. In some arrangements, the FP dielectric layer 162 may comprise a “thick” silicon oxide layer having a thickness of about 30 nanometers (nm) to 120 nm. Depending on implementation, an example gate oxide layer (not explicitly shown) formed over the body region 154 and a portion of the drift region 156 may comprise a “thin” oxide layer having a thickness of about 8 nm to 12 nm.

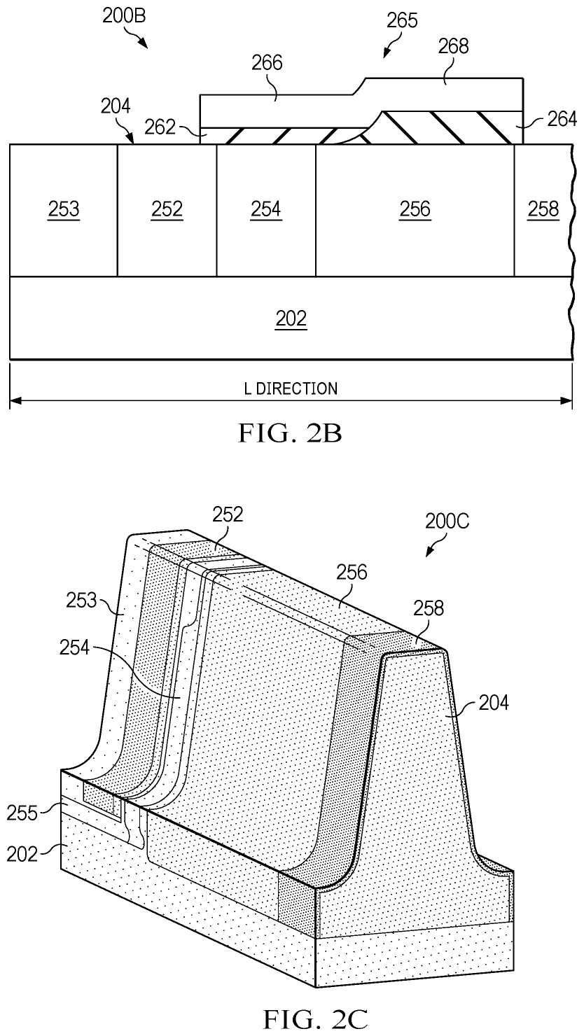

FIGS. 2A-2C depict examples that are similar to the examples set forth above, where additional aspects and features relative to an example corrugated channel structure are illustrated. In particular, FIG. 2A depicts a 3D perspective view of a corrugated channel structure 204 formed in a substrate 202 of an IC device 200A or a portion thereof, including an STI region 206 provided for isolation. The corrugated channel structure 204 includes a back gate 253 formed adjacent to a source region 252 of the corrugated channel structure 204. A drain region 258 is formed at an end opposite to the source region 252 of the corrugated channel structure 204. An electrode structure 265 comprising polysilicon or other suitable conductive material may be formed over a body region and a drift region (hidden in this view) of the corrugated channel structure 204. In some arrangements, the electrode structure 265 may include a gate 266 and a field plate 268 that are electrically isolated from the body region and the drift region of the corrugated channel structure 204 (which are disposed between the source region 252 and the drain region 258), by a “thin” gate oxide 262 and a “thick” FP oxide 264, respectively, similar to the arrangement set forth above with respect to FIG. 1C. FIG. 2B depicts a cross-sectional view 200B of the corrugated channel structure 204 through a central plane λ′-X″ shown in FIG. 2A, where the body region 254 and the drift region 256 are explicitly shown. In some arrangements, the body region 254 and the drift region 256 may be electrically isolated from the gate 266 and the field plate 268 by respective portions of the gate oxide 262 and the FP oxide 264. Although not shown in FIGS. 2A and 2B, a drain-tied field plate may also be optionally formed in some additional and/or alternative examples. Further, the gate 266 and the field plate 268 may be electrically isolated in some additional and/or alternative examples.

Depending on implementation, various aspects and features of the example IC devices 100A/200A including the corrugated channel structures 104/204 as set forth above may be fabricated according to a FinFET fabrication flow described in U.S. Pat. Nos. 10,978,559; 11,152,506; 11,437,496; 11,508,842 and/or U.S. Patent Appl. Publ. No. 2022/0123130, each of which is incorporated by reference in its entirety for all purposes, which may be individually and/or collectively referred to as “incorporated disclosures”. Further, whereas some example devices are shown herein as having recessed oxide in the trenches, it is not a requirement for purposes of the present disclosure. Accordingly, example dopant blocking configurations set forth herein may be implemented in a variety of FinFET devices as described in the present disclosure, which may be generally representative of multi-fin devices where the trench bottoms are part of the device active area.

FIG. 2C depicts a 3D perspective view 200C of an example corrugated channel structure, e.g., corrugated channel structure 204, illustrating different regions that may receive various types of dopants according to some examples of the present disclosure. In one implementation, the substrate 202 may be doped with a dopant of a first conductivity type, e.g., a p-type dopant such as boron. In one implementation, the source region 252 and the drain region 258 may be doped with a dopant of a second conductivity type, e.g., an n-type dopant such as phosphorus in an NSD implant process. In one implementation, the drift region 256 may be doped with one or more dopant species comprising phosphorus, arsenic, etc., in a drift implant process (e.g., NDRIFT implant process). In one implementation, one or more dopants of p-type and/or n-type may be introduced proximate to the source region 252 for forming a DWELL region 255 in the body 254 in a DWELL implant process. In one implementation, the back gate region 253 may be doped with a p-type dopant in a PSD implant process.

Without limitation, examples of the present disclosure may be configured to provide the following dopant concentrations and junction depths in the appropriate regions of the corrugated channel structure 204: an NSD implant process configured to dope the source and drain regions 252, 258 with phosphorus having a target concentration of about 1.0×10²¹ atoms/cm³ and a junction depth of about 80 nm to 100 nm; a first NDRIFT implant process configured to dope the drift region 256 with phosphorus having a target concentration of about 1.0×10¹⁷ atoms/cm³ and a junction depth of about 50 nm to 100 nm; a second NDRIFT implant process configured to dope the drift region 256 with arsenic having a target concentration of about 1.0× to 5.0×10¹⁶ atoms/cm³ and a junction depth of about 50 nm to 100 nm a p-type DWELL implant process configured to dope the DWELL region with boron having a target concentration of about 1.0×10¹⁸ atoms/cm³ and a junction depth of about 50 nm to 100 nm; an n-type DWELL implant process configured to dope the DWELL region with arsenic having a target concentration of about 1.0×10²⁰ atoms/cm³ and a junction depth of about 40 nm to 60 nm; and a PSD implant process configured to dope the back gate region 253 with boron having a target doping concentration of about 1.0×10²¹ atoms/cm³ and a junction depth of about 80 nm to 100 nm.

According to examples herein, any combination and/or sub-combination of the foregoing implant processes may be configured to provide conformal doping in various components of the channel topography, e.g., the top surfaces and the sidewalls of the corrugated channel structures as well as the bottom surfaces of the trenches, using beamline implant techniques in conjunction with selective blocking of the various components.

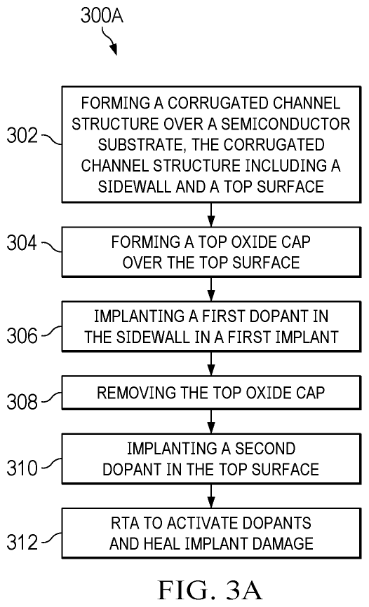

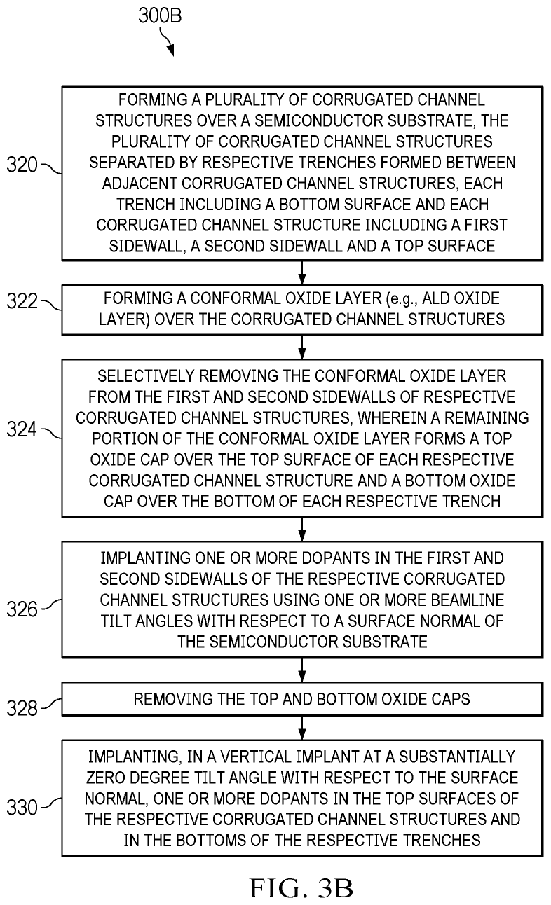

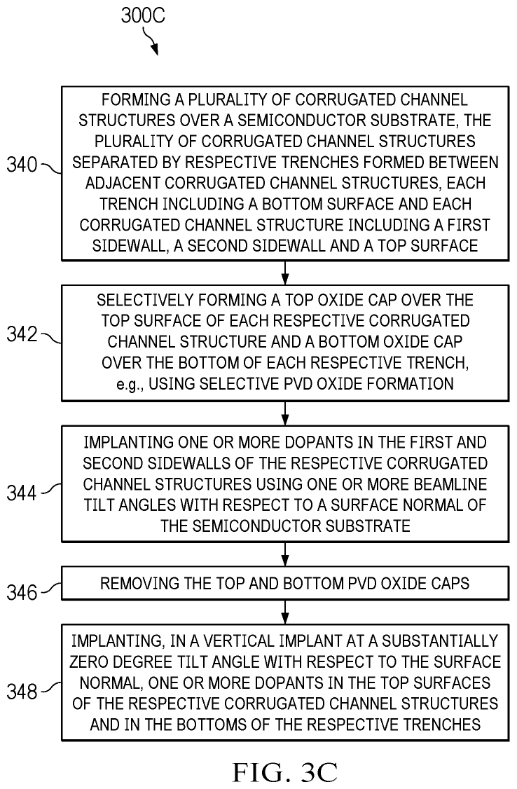

FIGS. 3A-3C are flowcharts of IC fabrication methods for conformally doping the corrugated channel structures of an IC device according to some examples of the present disclosure. In particular, FIG. 3A depicts a flowchart of a generalized scheme corresponding to a fabrication method 300A in an example implementation. At block 302, one or more corrugated channel structures may be formed in or over a semiconductor substrate, where a corrugated channel structure includes a sidewall, e.g., a first sidewall and a second sidewall, and a top surface. At block 304, a top oxide cap may be formed over the respective top surfaces of the corrugated channel structures while the sidewalls of the corrugated channel structures may remain exposed or covered with a sufficiently thin oxide that does not block a beamline implant. As will be set forth below in further detail, the formation of a blocking top oxide cap may be accomplished using a variety of techniques depending on implementation. Further, the thicknesses of the top oxide caps as well as any sidewall oxide layer (where remaining) may be optimized for a particular implementation of implant technology.

At block 306, one or more dopants, e.g., a first dopant, may be implanted in the sidewalls in a first implant process, e.g., using one or more beamline tilt angles with respect to a surface normal of the semiconductor substrate. For example, the first sidewalls of the corrugated channel structures may be implanted using a first beamline tilt angle whereas the second sidewalls of the corrugated channel structures may be implanted using a second beamline tilt angle. Further, the type of dopants implanted into the sidewalls may vary depending on which region of the corrugated channel structures is exposed for implanting via a multi-mask scheme where each region may be sequentially exposed using a suitably patterned mask. After the sidewalls of the corrugated channel structures are implanted, the top oxide caps may be removed, e.g., wet etch or a plasma etch (block 308). Thereafter, another implant process, e.g., a vertical implant process at a substantially zero tilt angle (e.g., 0⁰±2⁰), with respect to the surface normal of the semiconductor substrate, may be configured to implant the exposed top surfaces of the corrugated channel structures using one or more dopants (e.g., a second dopant), as set forth at block 310. Similar to the sidewall implanting, the top surfaces of the different regions of the corrugated channel structures may be implanted using different dopants where the different regions may be exposed in a sequential manner based on a multi-mask process. At block 312, a suitable rapid thermal anneal (RTA) process may be performed to activate the dopants and heal any damage caused by the beamline implanting processes. In some examples, the RTA process may comprise a thermal anneal at around 1000° C. to 1200° C. for about 10 to 15 seconds, without limitation. Additional details regarding an example beamline implant process are described in U.S. patent application Ser. No. 18/496,697, filed Oct. 27, 2023, which is incorporated by reference herein for all purposes. Additional details regarding selectively implanting different regions of corrugated channel structures using different masking schemes are described in in U.S. patent application Ser. No. 18/391,307, filed Dec. 20, 2023, which is incorporated by reference herein for all purposes.

FIG. 3B depicts a flowchart of a fabrication method 300B that includes an implant blocking scheme based on atomic layer deposition (ALD) in an example implementation. At block 320, a plurality of corrugated channel structures may be formed in or over a semiconductor substrate, where the plurality of corrugated channel structures are separated by respective trenches formed between adjacent corrugated channel structures, each trench including a bottom surface and each corrugated channel structure including a first sidewall, a second sidewall and a top surface. At block 322, a conformal oxide layer of suitable thickness (e.g., about 200 nm to 500 nm) may be formed over the corrugated channel structures using a suitable deposition process, e.g., ALD. In some arrangements, the conformal oxide layer formed over the corrugated channel structures may be comprised of continuously connected horizontal portions covering the top surfaces and the bottom surfaces as well as vertical portions covering the sidewalls of the corrugated channel structures. In some arrangements, the horizontal portions may have a density (e.g., a first density) and/or a thickness (a first thickness) greater than a density (e.g., a second density) and/or thickness (e.g., a second thickness) of the substantially vertical portions of the conformal oxide layer covering the first and second (sloped) sidewalls of the respective corrugated channel structures. In some arrangements, accordingly, the differential densities and/or thicknesses of the horizontal oxide portions and the vertical oxide portions may be advantageously manipulated to facilitate a highly selective etching process, e.g., having a selectivity of 50:1 or more, for selectively removing the conformal oxide layer from the first and second sidewalls of respective corrugated channel structures. In an example implementation, HF may be used as an etchant in a wet etch process to selectively remove the conformal oxide portions from the sidewalls, where a remaining portion of the conformal oxide layer forms a top oxide cap over the top surface of each respective corrugated channel structure and a bottom oxide cap over the bottom surface of each respective trench, as set forth at block 324.

In some arrangements, the sidewalls of the corrugated channel structures may be completely stripped of any oxide, depending on etch selectivity, although it is not a necessary requirement. In some implementations, an example process may be configured to form thicker top and bottom oxide caps while leaving a thinner sidewall oxide over the respective sidewalls where the thinner sidewall oxide does not block angled beamline implants having sufficient implant energy. At block 326, one or more dopants may be implanted in the first and second sidewalls of the respective corrugated channel structures, e.g., using one or more beamline tilt angles. In some arrangements, a first dopant may therefore be implanted in the first and second sidewalls of the respective corrugated channel structures using a nonzero beamline tilt angle with respect to a surface normal of the semiconductor substrate, as previously noted, which may depend on the region and/or implant process involved (e.g., NDRIFT, PSD/NSD, DWELL, etc.). At block 328, the top and bottom oxide caps may be completely or substantially removed using a wet etch or a plasma etch. At block 330, one or more dopants may be implanted in the top surfaces and the bottom surfaces using a vertical implant process, e.g., at a substantially 0° tilt beamline angle with respect to the surface normal of the substrate surface. In some arrangements, a second dopant (having the same conductivity type as the first dopant or a different conductivity type) may therefore be implanted in the top surfaces of the respective corrugated channel structures and in the bottom surfaces of the respective trenches, depending on the region and consistent with the implant process involved (e.g., NDRIFT, NSD/PSD, DWELL, etc.), using a beamline tilt angle about parallel to the surface normal of the semiconductor substrate. Thereafter, an anneal process may be performed for activating the implanted dopants in the corrugated channel structures and associated trenches as noted previously. In some additional and/or alternative arrangements, a variety of etching process combinations may be implemented with respect to selectively removing the sidewall oxide portions (for forming the top and bottom oxide caps) and the subsequent removal of the top and bottom oxide caps, e.g., depending on the thickness of the conformal oxide layer, relative densities and/or thicknesses of the vertical and horizontal portions of the conformal oxide layer, etc.

FIG. 3C depicts a flowchart of a fabrication method 300C that includes an implant blocking scheme based on physical vapor deposition (PVD) in an example implementation. At block 340, a plurality of corrugated channel structures may be formed in or over a semiconductor substrate as set forth previously. Similar to the arrangements described above, the plurality of corrugated channel structures may be separated by respective trenches formed between adjacent corrugated channel structures depending on applicable pitch design requirements, where each trench includes a bottom surface and each corrugated channel structure includes a first sidewall, a second sidewall and a top surface. At block 342, a top oxide cap over the top surface of each respective corrugated channel structure and a bottom oxide cap over the bottom of each respective trench may be selectively formed, where the top oxide caps and the bottom oxide caps may have respective thicknesses (e.g., using an anisotropic deposition process) sufficient to block angled or vertical beamline implants. In some arrangements, the selective formation of the top and bottom oxide caps may leave the sidewalls of the corrugated channel structures completely or substantially devoid of a sidewall oxide. Where there is a sidewall oxide, it may be sufficiently thin so as not to block angled sidewall implant processes without requiring a sidewall oxide etch process. Where the sidewall oxide is thick, a selective wet etch process (e.g., using HF) may be used to remove or thin the sidewall oxide to facilitate angled beamline implant processes. Depending on the anisotropy of oxide cap formation and/or the selectivity of any optional etch, the sidewalls may be completely devoid of any oxide, although it is not a necessary requirement, as noted previously. In some arrangements where there may be a sidewall oxide present, the top oxide caps and the bottom oxide caps may have a first thickness (e.g., 200 nm to 500 nm) that is greater than a second thickness of the sidewall oxide portions formed over the first and second sidewalls of the respective corrugated channel structures.

At block 344, one or more dopants may be implanted in the first and second sidewalls of the respective corrugated channel structures, e.g., using one or more beamline tilt angles. As noted previously, a first dopant (e.g., having a first conductivity type) may therefore be implanted in the first and second sidewalls of the respective corrugated channel structures using a nonzero beamline tilt angle with respect to a surface normal of the semiconductor substrate, which may depend on the region and/or implant process involved (e.g., NDRIFT, PSD/NSD, DWELL, etc.). At block 346, the top and bottom oxide caps may be completely or substantially removed using a wet etch or a plasma etch. At block 348, one or more dopants may be implanted in the top surfaces and the bottom surfaces using a vertical implant process, e.g., at a substantially 0° tilt beamline angle with respect to the surface normal of the substrate surface. In some arrangements, a second dopant (e.g., having the same conductivity type as the first dopant or a different conductivity type) may be implanted in the top surfaces of the respective corrugated channel structures and in the bottom surfaces of the respective trenches, depending on the region and/or implant process involved (e.g., NDRIFT, NSD/PSD, DWELL, etc.), using a beamline tilt angle about parallel to the surface normal of the semiconductor substrate. Thereafter, an anneal process may be performed for activating the implanted dopants in the corrugated channel structures and associated trenches as noted previously. Similar to the ALD arrangements set forth above, different combinations of wet and plasma etch processes may be implemented depending on the anisotropy of the PVD oxide cap formation.

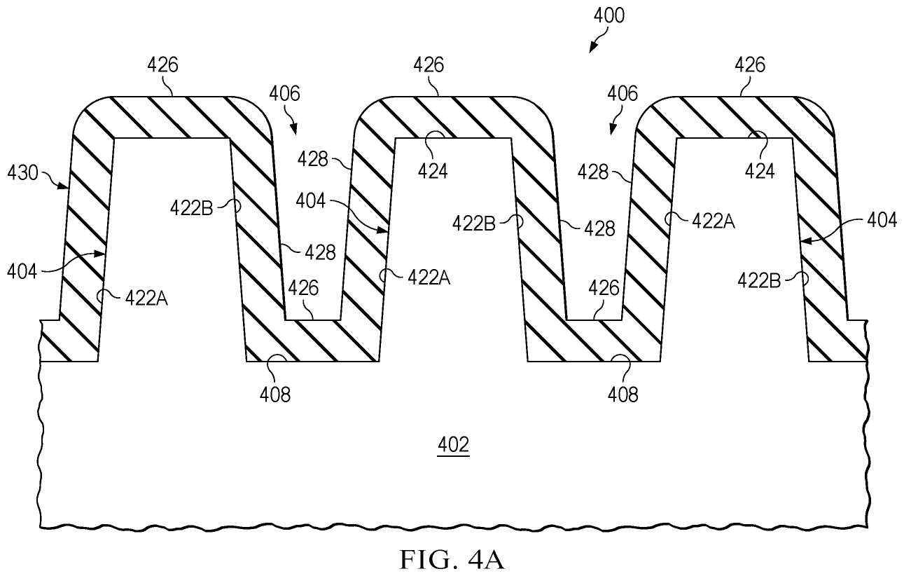

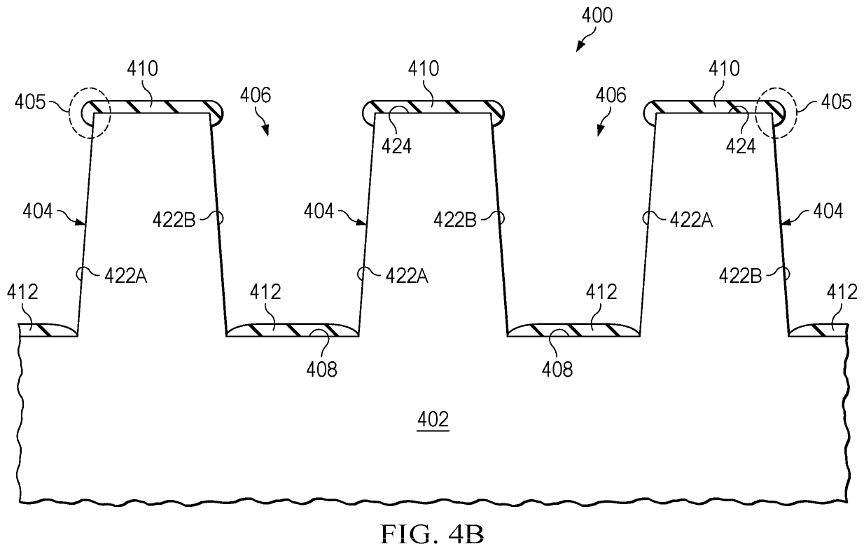

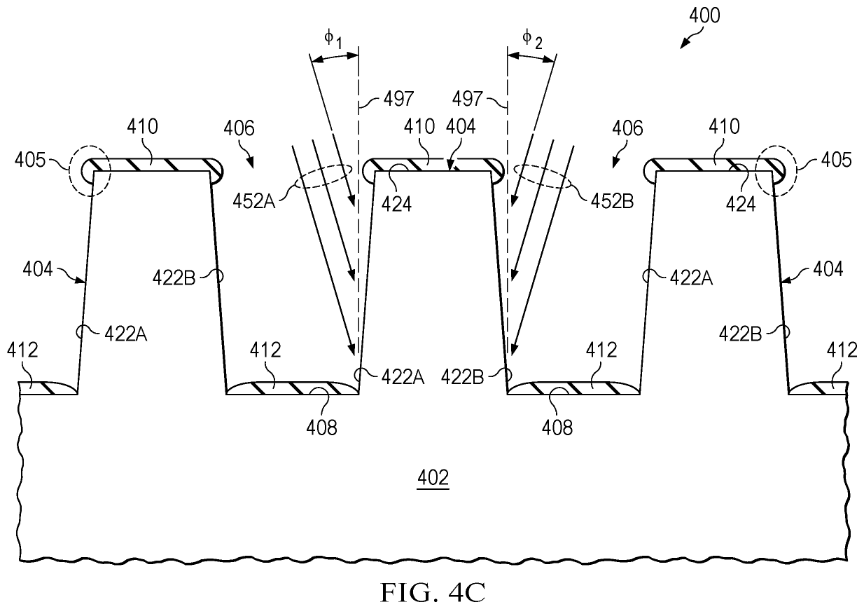

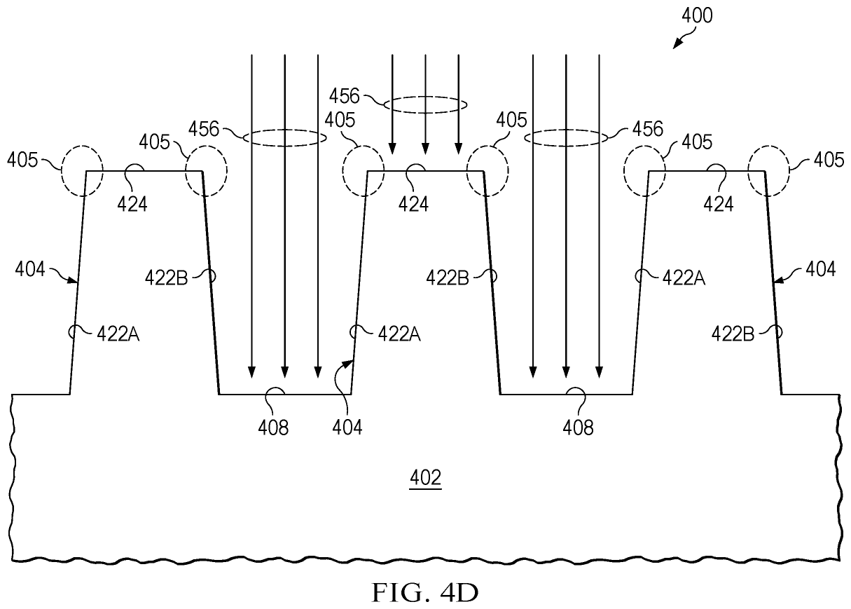

FIGS. 4A-4D depict cross-sectional views of an IC device 400 at various stages of formation for fabricating conformally doped corrugated channel structures according to an example of the present disclosure involving ALD oxide cap blocking. Specifically referring to FIG. 4A, the IC device 400 at an early fabrication stage is shown, where one or more fins or corrugated channel structures 404 are formed in a semiconductor substrate 402, e.g., as set forth at block 320 of FIG. 3B. Whereas the semiconductor substrate 402 may predominantly comprise suitably doped silicon as substate material in some examples, other semiconductor materials such as, Ge, SiGe, GaAs, SiC, GaN, other Group III-V materials, etc., may be used in some implementations, as noted previously, where one or more epitaxial layers or single-crystal layers may be formed or provided as part of the semiconductor substrate 402 in some arrangements. In some examples, the semiconductor substrate 402 may be part of a larger semiconductor substrate (which may include other electronic circuitry and components, not shown in the Figures) that is suitably doped depending on the type of FinFET to be fabricated in the semiconductor substrate 402. Depending on application, an example FinFET implementation may be based on a variety of technologies and may comprise a device including analog, digital and/or mixed signal device designs that may be fabricated using at least a portion of a process flow disclosed in the “incorporated disclosures” cited in this present disclosure. In some examples, a combination of semiconductor technologies may be implemented, where different technologies suitable for respective types of product design may be integrated within the same chip or IC device, e.g., linear BiCMOS or LBC (a bipolar-CMOS combination technology where MOS and bipolar technology may be used for analog functions and CMOS may be used for digital logic design), BCD (a bipolar-CMOS-DMOS combination technology where DMOS may be integrated within the IC device for power and high-voltage portions that also has analog and digital portions), and the like. Accordingly, without being limited to a particular implementation or technology node, the semiconductor substrate 402 may comprise a portion of a semiconductor process wafer, e.g., an IC die, that may be processed to include to any combination of epitaxial layers, buried layers, laterally diffused extensions, N-wells, P-wells, deep wells, shallow wells, reduced surface field (RESURF) layers formed over the dielectric layers of SOI substrates, etc. Further, the example semiconductor substrate 402 may include various isolation structures for dielectrically isolating the constituent layers, regions, well structures, etc., using a variety of isolation techniques, e.g., shallow trench isolation (STI), local oxidation of silicon (LOCOS), etc., not shown herein for the sake of clarity, which may be formed at or during any suitable front-end-of-line (FEOL) stage(s) integrated within a flow as set forth herein. Likewise, thermal oxide layers, nitride hard mask layers, etc. that may be provided as part of a FinFET fabrication flow are not specifically shown in the cross-sectional view of the drawing Figures.

The corrugated channel structures 404 may be separated by respective troughs or trenches 406 formed between adjacent corrugated channel structures 404, where the trenches 406 having bottom surfaces 408 may be formed by an RIE process as noted previously. Similar to the examples described in the foregoing sections, the corrugated channel structures 404 may each have a top surface 424 and two sidewalls 422A, 422B. A conformal ALD oxide layer 430 having a suitable thickness may be formed over the corrugated channel structures 404 and the bottom surfaces 408 of the trenches 406 (e.g., as set forth at block 322 of FIG. 3B). In some arrangements, the ALD oxide layer 430 may comprise horizontal portions 426 formed over the top surfaces 424 and bottom surfaces 408 that are denser and/or thicker than vertical portions 428 formed over the sidewalls 422A, 422B although it is not a necessary requirement.

FIG. 4B depicts a stage where the ALD oxide layer 430 has been etched in a selective sidewall oxide etch (e.g., using dilute HF) to form top oxide caps 410 over the top surfaces 424 of the corrugated channel structures 404 and bottom oxide caps 412 over the bottom surfaces 408 of the trenches 406. In the disclosed examples, the sidewalls 422A, 422B of the corrugated channel structures 404 are illustrated as being devoid of the ALD oxide material (e.g., as set forth at block 324). FIG. 4C depicts a stage where the sidewalls 422A, 422B are doped with one or more dopant species using one or more angled beamline implants 452A, 452B at suitable tilt angles, ϕ₁, ϕ₂, e.g., 4° to 10°, with respect to a surface normal 497 of the semiconductor substrate 402 (e.g., as set forth at block 326). FIG. 4D depicts a stage where the top and bottom oxide caps 410, 412 have been removed and one or more vertical beamline implants 456 are effectuated for implanting suitable dopant species in the top surfaces 424 and the bottom surfaces 408 as previously described, e.g., as set forth at blocks 328 and 330 of FIG. 3B.

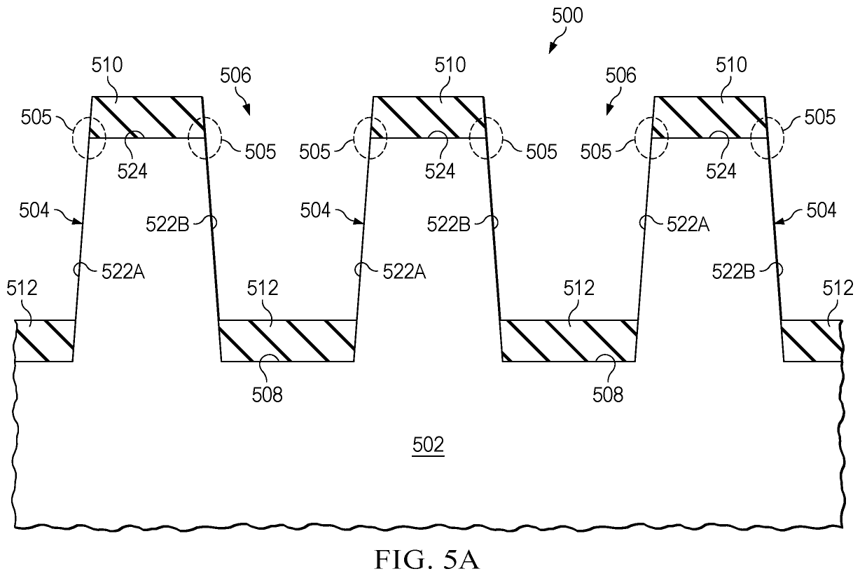

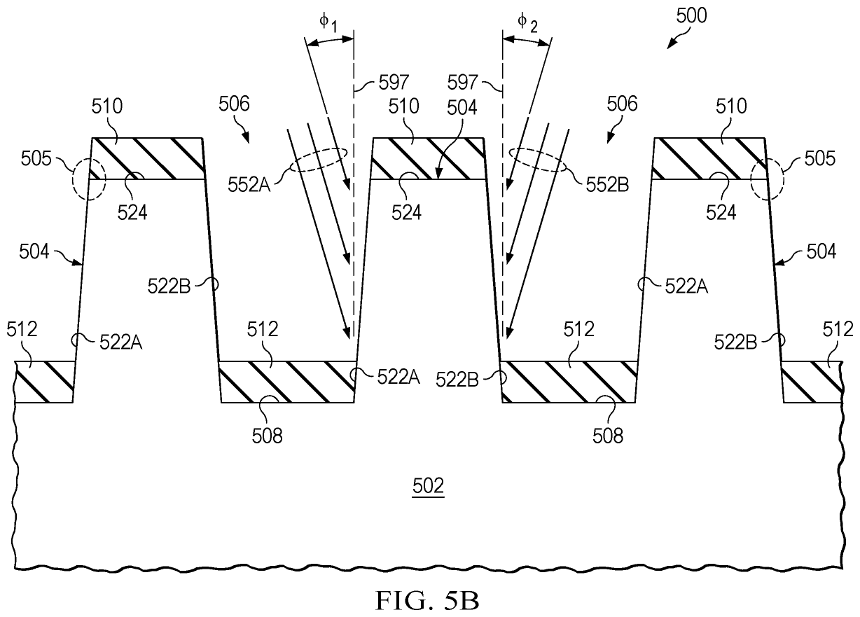

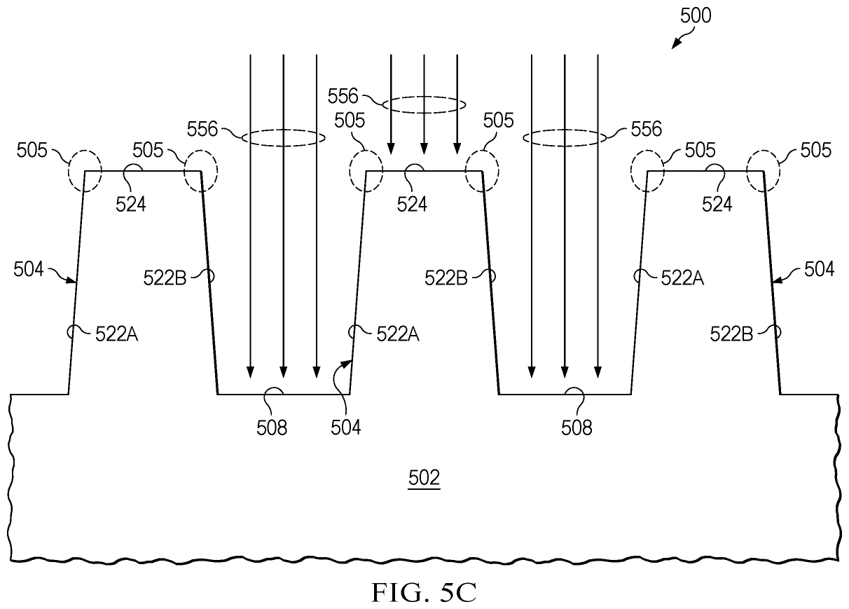

FIGS. 5A-5C depict cross-sectional views of an IC device 500 at various stages of formation for fabricating conformally doped corrugated channel structures according to an example of the present disclosure involving PVD oxide cap blocking. Specifically referring to FIG. 5A, the IC device 500 at an early fabrication stage is shown, where one or more fins or corrugated channel structures 504 separated by trenches 506 are formed in a semiconductor substrate 502, e.g., as set forth at block 340 of FIG. 3C. As with the ALD-based examples described above, a simplified cross-sectional view depicting selectively formed top and bottom PVD oxide caps 510, 512 covering top surfaces 524 of the corrugated channel structures 504 and bottom surfaces 508 of the trenches 506, respectively, are shown herein for the sake of clarity (e.g., corresponding to the acts of block 342). In some examples, sidewalls 522A, 522B of the respective corrugated channel structures 504 may be devoid of PVD oxide material, although some additional and/or alternative arrangements may have a PVD oxide film formed over the sidewalls 522A, 522B that may require an additional fabrication step for thinning or removing the sidewall oxide material as noted previously.

FIG. 5B depicts a stage where the sidewalls 522A, 522B are doped with one or more dopant species using one or more angled beamline implants 552A, 552B at suitable tilt angles, ϕ₁, ϕ₂, e.g., 4° to 10°, with respect to a surface normal 597 of the semiconductor substrate 502 (e.g., as set forth at block 344). FIG. 5C depicts a stage where the top and bottom oxide caps 510, 512 have been removed and one or more vertical beamline implants 556 are effectuated for implanting suitable dopant species in the top surfaces 524 and the bottom surfaces 508 of the IC device 500 as previously described, e.g., as set forth blocks 346 and 348 of FIG. 3C.

In the example ALD/PVD-based implant blocking schemes set forth above, the top surface material of the corrugated channel structures 404, 504 may not be significantly consumed during the formation of the blocking oxide caps. Accordingly, respective top surface corners 405, 505 of the corrugated channel structures 404, 504 may exhibit a sharper corner profile in contradistinction to more rounded corners that may be seen in a masking scheme involving thermal oxidation for purposes of providing conformal doping of the corrugated channel topography of a FinFET device.

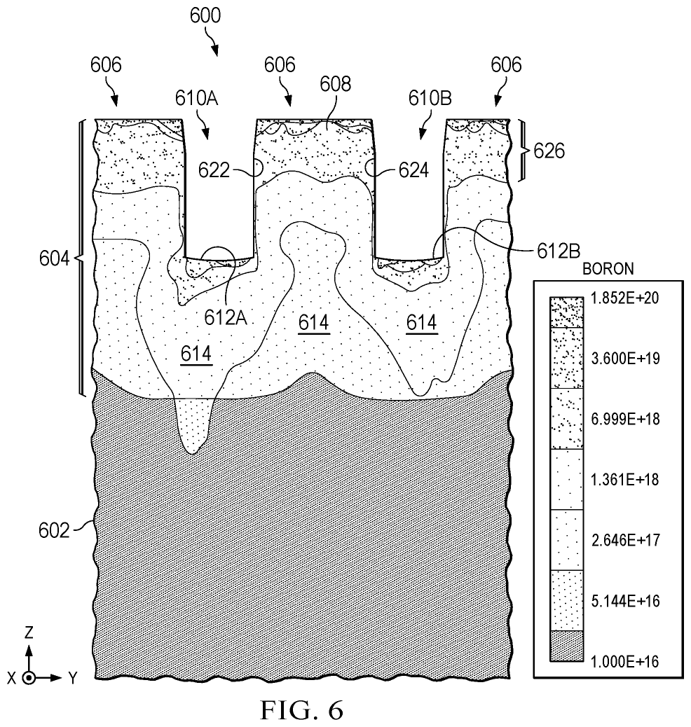

FIG. 6 depicts a simulated dopant profile across a portion of an IC device 600 including one or more corrugated channel structures 606, which may be representative of the example devices 400, 500 described above, where an example device may be illustrative of a variety of multi-fin FET devices as previously described. By way of illustration, the IC device 600 includes a semiconductor substrate 602 having a corrugated top portion 604 comprising corrugated channel structures 606, each having a body 608 with an upper portion 626 and lateral sidewall portions 622 and 624, that are separated by respective trenches, e.g., trenches 610A, 610B. A p-type dopant, e.g., boron, is implanted using angled beamline implants and a vertical implant in a simulated process flow. As can be seen from FIG. 6, a substantially uniform dopant profile is seen across the topography of the corrugated channel structures 606, e.g., across a width of the body 608 along a horizontal axis (e.g., Y-axis) parallel to a horizontal surface of the substrate 602. Additionally, substantially uniform dopant profiles are also seen near the bottoms 612A, 612B of the trenches 610A, 610B as well as substrate regions 614 underlying the corrugated channel structures 606. As used herein, the term “substantially uniform” may be used to refer to +12 one order of magnitude, or otherwise as illustrated in the example of FIG. 6.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, LPCVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride. Still further, whereas example FinFETs are depicted with subsurface fins, e.g., where the fins are formed by etching into a substrate for creating trenches that separate the resulting fins, aspects of the present disclosure may also be implemented in other FinFET architectures, e.g., including where the fins are formed or grown over a substrate as a set of protruding fins extending from the substrate's surface.

In at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A method of fabricating an integrated circuit (IC), comprising:
forming a corrugated channel structure over a semiconductor substrate, the corrugated channel structure including a sidewall and a top surface;
forming a top oxide cap over the top surface;
implanting a first dopant in the sidewall in a first implant;
removing the top oxide cap; and
implanting a second dopant in the top surface.

2. The method as recited in claim 1, wherein the corrugated channel structure is one of a first corrugated channel structure and an adjacent second corrugated channel separated by a trench including a bottom surface, and further comprising forming a bottom oxide cap covering the bottom surface concurrently with forming the top oxide cap.

3. The method as recited in claim 2, further comprising removing the bottom oxide cap concurrently with removing the top oxide cap.

4. The method as recited in claim 1, wherein the top oxide cap is formed by first forming a conformal oxide layer over the top surface and the sidewall surface, and then selectively removing the conformal oxide layer over the sidewall surface.

5. The method as recited in claim 4, wherein the conformal oxide layer is selectively removed over the sidewall surface by a wet etch.

6. The method as recited in claim 4, wherein the conformal oxide layer is formed by atomic layer deposition (ALD).

7. The method as recited in claim 1, wherein the top oxide cap is formed by selective physical vapor deposition (PVD) of the top surface.

8. The method as recited in claim 2, wherein the top oxide cap and the bottom oxide cap are removed by a wet etch.

9. The method as recited in claim 2, wherein the top oxide cap and the bottom oxide cap are removed by a plasma etch.

10. A method of fabricating an integrated circuit (IC), comprising:
forming a plurality of corrugated channel structures over a semiconductor substrate, the plurality of corrugated channel structures separated by respective trenches formed between adjacent corrugated channel structures, each trench including a bottom surface and each corrugated channel structure including a first sidewall, a second sidewall and a top surface;
forming a conformal oxide layer over the corrugated channel structures;
selectively removing the conformal oxide layer from the first and second sidewalls of respective corrugated channel structures, wherein a remaining portion of the conformal oxide layer forms a top oxide cap over the top surface of each respective corrugated channel structure and a bottom oxide cap over the bottom surface of each respective trench;
implanting a first dopant in the first and second sidewalls of the respective corrugated channel structures using a nonzero beamline tilt angle with respect to a surface normal of the semiconductor substrate;
removing the top and bottom oxide caps; and
implanting a second dopant in the top surfaces of the respective corrugated channel structures and in the bottom surfaces of the respective trenches using a beamline tilt angle about parallel to the surface normal of the semiconductor substrate.

11. The method as recited in claim 10, wherein the conformal oxide layer is formed by atomic layer deposition (ALD).

12. The method as recited in claim 10, wherein the conformal oxide layer is comprised of horizontal portions having a first density formed over the top surfaces and the bottom surfaces, and vertical portions having a second density less than the first density formed over the first and second sidewalls of the respective corrugated channel structures.

13. The method as recited in claim 10, wherein the conformal oxide layer is selectively removed from the first and second sidewalls of the respective corrugated channel structures using a wet etch.

14. The method as recited in claim 10, wherein the top oxide caps and the bottom oxide caps are removed by a wet etch.

15. The method as recited in claim 13, wherein the top oxide caps and the bottom oxide caps are removed by a plasma etch.

16. A method of fabricating an integrated circuit (IC), comprising:
forming a plurality of corrugated channel structures over a semiconductor substrate, the plurality of corrugated channel structures separated by respective trenches formed between adjacent corrugated channel structures, each trench including a bottom and each corrugated channel structure including a first sidewall, a second sidewall and a top surface;
selectively forming a top oxide cap over the top surface of each respective corrugated channel structure and a bottom oxide cap over the bottom of each respective trench;
implanting one or more dopants in the first and second sidewalls of the respective corrugated channel structures using one or more beamline tilt angles with respect to a surface normal of the semiconductor substrate;
removing the top and bottom oxide caps; and
implanting, in a vertical implant, one or more dopants in the top surfaces of the respective corrugated channel structures and in the bottoms of the respective trenches.

17. The method as recited in claim 16, wherein the top oxide caps and the bottom oxide caps are formed by physical vapor deposition (PVD).

18. The method as recited in claim 16, wherein the top oxide caps and the bottom oxide caps have a first thickness greater than a second thickness of sidewall oxide portions formed over the first and second sidewalls of the respective corrugated channel structures.

19. The method as recited in claim 18, wherein the top oxide caps and the bottom oxide caps are removed by a wet etch.

20. The method as recited in claim 19, wherein the sidewall oxide portions are removed by a plasma etch.
